(19) United States
(12) Patent Application Publication
(10) Pub. No.: US 2009/0184332 A1
(43) Pub. Date: Jul. 23, 2009

(54) Package structure module with high density electrical connections and method for packaging the same

(76) Inventor: Ming-Che Wu, Tsao Tuen (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/010,235

(22) Filed: Jan. 23, 2008

(51) Int. Cl. H01L 33/00

(52) U.S. Cl. 257/88; 438/28; 257/E33.058

(57) ABSTRACT

A package structure module with high density electrical connections includes a drive IC structure, an LED array structure, and a plurality of conductive structures. The drive IC structure has a plurality of first open grooves formed on a lateral wall thereof. The LED array structure has a plurality of second open grooves formed on a lateral wall thereof to respectively face the first open grooves. Each conductive structure traverse the corresponding first open groove and the corresponding second open groove in order to electrically connect between the drive IC structure and the LED array structure.

### BACKGROUND OF THE INVENTION

1. Field of the Invention

The present invention relates to a package structure module and a method for packaging the same, and particularly relates to a package structure module with high density electrical connections and a method for packaging the same.

2. Description of the Related Art

In the typical printer technology, a laser is used as a light source in a printer head to scan and transfer the printing information as light signals to a rotating drum in order to generate electrostatic latent images formed on the rotating drum. Moreover, the printing method further includes a toner absorbing step, a transferring step, a hot pressing step, an electrostatic discharging step etc. to reach printing. However, a laser printer head of the prior art has many optical components, and the mechanism of the laser printer head is complex and the optical path of the laser printer head is very long. Hence, the optical structure is quite complex and difficult to reduce in size when using a laser as light source. Therefore, the current trend is toward using light emitting diodes to replace lasers as the light sources in printer heads, which can simplify the optical structure.

Thereby, it is a requirement to reduce the volume of each light emitting diode so as to increase the resolution of the printer. More light emitting diodes can be fitted per unit area on the printer head when the volume of each light emitting diode is reduced. According to the typical packaging method, a highly precise packaging apparatus is required to arrange the light emitting diode arrays and the driver integrated circuits so that they are exactly parallel to each other in a printed circuit board. Then, a wire bonding process is performed to form about 5000 wires between the light emitting diode arrays and the driver integrated circuits if the resolution of the printer is 600 dpi (dots per inch) of A4 size paper. The driver integrated circuits drive the light emitting diode arrays through these wires.

A highly exact and dense wire bonding process in the foregoing method increases the difficulty of the packaging process. This reduces the product yield and indirectly raises the manufacturing costs. Moreover, reducing the volume of the light emitting diodes in order to increase the resolution of the printer, further increases the packaging difficulty.

Therefore, a new package structure and method thereof is required to resolve the foregoing problems.

### SUMMARY OF THE INVENTION

One particular aspect of the present invention is to provide a package structure module with high density electrical connections and a method for packaging the same. The package structure module is an LED (Light Emitting Diode) array structure module, and the LED array structure module is a light exposure module that can be applied to an EPG (Electrophotography) printer.

The features of the present invention include (1) manufacturing concave grooves and pads electrically connected to each other on an LED array structure and a drive IC structure; (2) electroplating solder materials onto the drive IC structure; (3) the drive IC structure and the LED array structure are approximated to each other and electrically disposed on a PCB (Printed Circuit Board), and there is a height difference between the drive IC structure and the LED array structure; (4) slanting the PCB by a predetermined angle during a reflow process in order to make the solder materials flow to the LED array structure on a low position to connect to the pads of the LED array structure. Hence, the present invention can reach a high density electrical connection with 600˜1200 dip. Therefore, the present invention can reduce product size, material cost, and manufacturing cost due to high density electrical connection.

In order to reach the above-mentioned aspects, the present invention provides a package structure module with high density electrical connections, including: a drive IC structure (a first structure), an LED array structure (a second structure), and a plurality of conductive structures. The drive IC structure has a plurality of first open grooves formed on a lateral wall thereof. The LED array structure has a plurality of second open grooves formed on a lateral wall thereof and close to the first open grooves. The conductive structures respectively traverse the first open grooves and the second open grooves in sequence in order to make the conductive structures electrically connect between the drive IC structure and the LED array structure.

In order to reach the above-mentioned aspects, the present invention provides a method for packaging a package structure module with high density electrical connections, including: providing a drive IC structure (a first structure) and an LED array structure (a second structure), the drive IC structure having a plurality of first open grooves formed on a lateral wall thereof, the LED array structure having a plurality of second open grooves formed on a lateral wall thereof and close to the first open grooves, and the LED array structure having a plurality of conductive materials formed on a top surface thereof.

Moreover, the method further includes: electrically disposing the drive IC structure and the LED array structure on a substrate; slanting the substrate by a predetermined angle during a reflow process in order to make the conductive materials change into liquid conductive materials and make the liquid conductive materials traverse the second open grooves and the first open grooves in sequence to flow to the LED array structure; and then cooling the liquid conductive materials to form a plurality of conductive structures electrically connected between the drive IC structure and the LED array structure.

In order to reach the above-mentioned aspects, the present invention provides a method for packaging a package structure module with high density electrical connections, including: providing a drive IC structure (a first structure) and an LED array structure (a second structure), the drive IC structure having a plurality of first open grooves formed on a lateral wall thereof and a plurality of conductive materials formed on a top surface thereof, and the LED array structure having a plurality of second open grooves formed on a lateral wall thereof and close to the first open grooves.

Moreover, the method further includes: electrically disposing the drive IC structure and the LED array structure on a substrate; slanting the substrate by a predetermined angle during a reflow process in order to make the conductive materials change into liquid conductive materials and make the liquid conductive materials traverse the first open grooves and the second open grooves in sequence to flow to the LED array structure; and then cooling the liquid conductive materials to form a plurality of conductive structures electrically connected between the drive IC structure and the LED array structure.

Therefore, the present invention does not need to use a wire-bonding process as in the prior art that requires a long time. Hence, the present invention not only can reduce product size, material cost, and manufacturing cost, but also increases production speed.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

The various objects and advantages of the present invention will be more readily understood from the following detailed description when read in conjunction with the appended drawings, in which:

FIG. 1 is a flowchart of a method for packaging a package structure module with high density electrical connections according to the first embodiment of the present invention;

FIGS. 1A1 to 1D2 are cross-sectional views of a package structure module with high density electrical connections according to the first embodiment of the present invention, at different stages of the packaging processes, respectively;

FIG. 2 is a flowchart of a method for packaging a package structure module with high density electrical connections according to the second embodiment of the present invention;

FIGS. 2A1 to 2D2 are cross-sectional views of a package structure module with high density electrical connections according to the second embodiment of the present invention, at different stages of the packaging processes, respectively;

FIG. 3 is a flowchart of a method for packaging a package structure module with high density electrical connections according to the third embodiment of the present invention;

FIGS. 3A1 to 3D2 are cross-sectional views of a package structure module with high density electrical connections according to the third embodiment of the present invention, at different stages of the packaging processes, respectively;

FIG. 4 is a flowchart of a method for packaging a package structure module with high density electrical connections according to the fourth embodiment of the present invention; and

FIGS. 4A1 to 4D2 are cross-sectional views of a package structure module with high density electrical connections according to the fourth embodiment of the present invention, at different stages of the packaging processes, respectively.

### DETAILED DESCRIPTION OF THE PREFERRED EMBODIMENTS

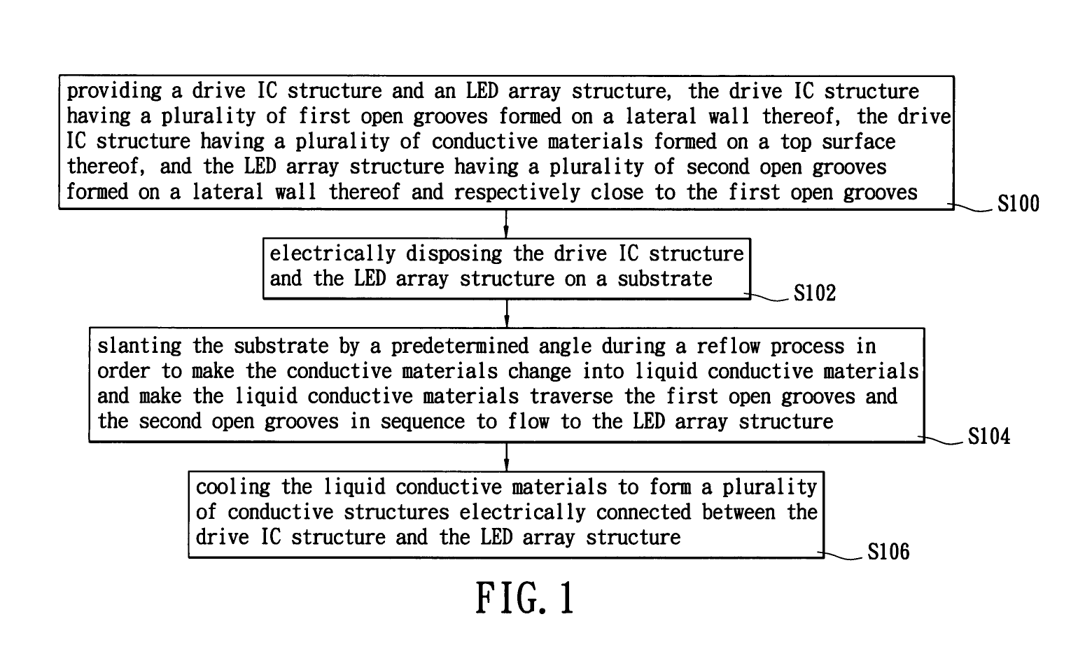

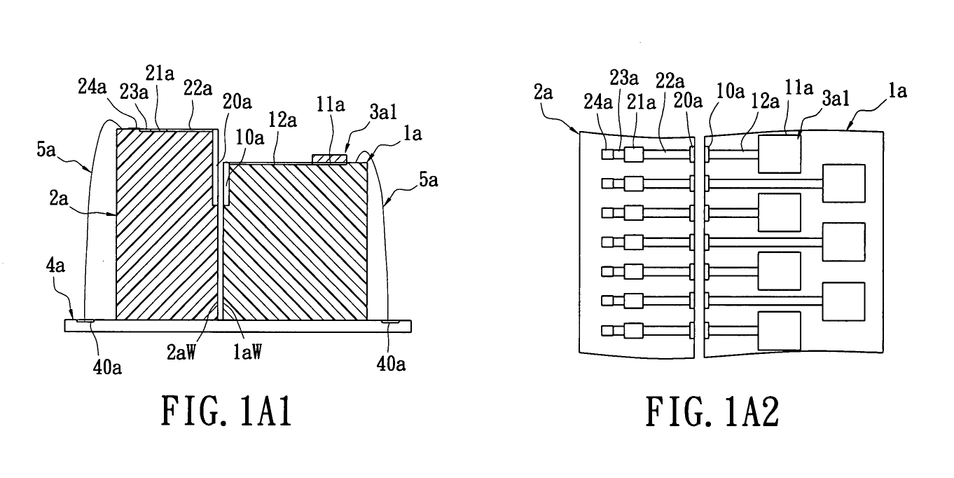

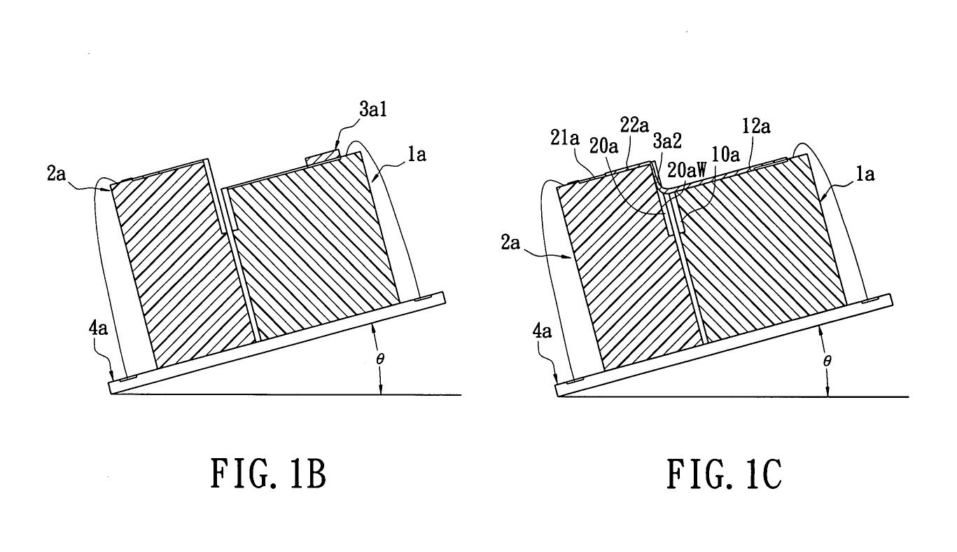

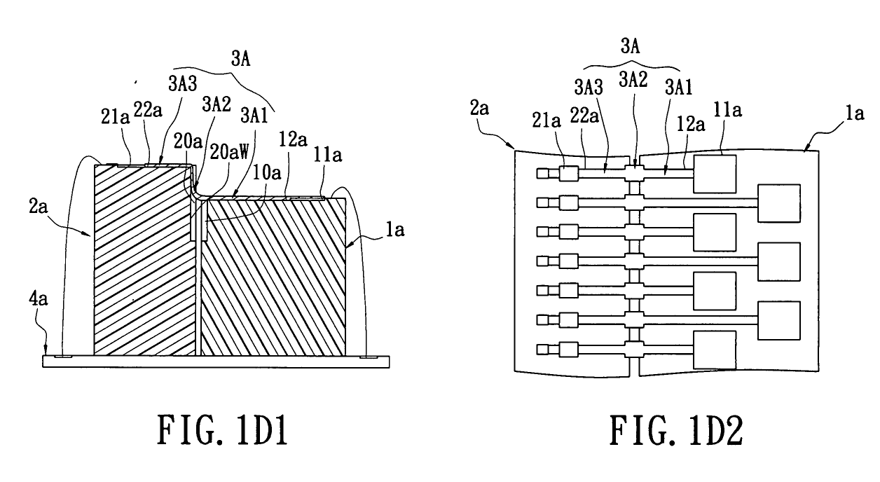

Referring to FIGS. 1 and 1A1 to 1D2, FIG. 1 shows a flowchart of a method for packaging a package structure module with high density electrical connections according to the first embodiment of the present invention, and FIGS. 1A1 to 1D2 show cross-sectional views of a package structure module with high density electrical connections according to the first embodiment of the present invention, at different stages of the packaging processes, respectively.

The first embodiment of the present invention provides a method for packaging a package structure module with high density electrical connections. The method includes following steps: referring to FIGS. 1, 1A1 and 1A2 (FIG. 1A2 shows a partial top view of FIG. 1A1), the step of S100 is: providing a drive IC structure 1a (a first structure) and an LED array structure 2a (a second structure), the drive IC structure 1a having a plurality of first open grooves 10a formed on a lateral wall 1aW thereof, the drive IC structure 1a having a plurality of conductive materials 3a1 formed on a top surface thereof, and the LED array structure 2a having a plurality of second open grooves 20a formed on a lateral wall 2aW thereof and respectively close to the first open grooves 10a.

Moreover, the LED array structure 2a has a height higher than that of the drive IC structure 1a. Each first open groove 10a and each second open grooves 20a are respectively formed on the lateral wall 1aW of the drive IC structure 1a and the lateral wall 2aW of the LED array structure 2a via etching. In addition, each first open groove 10a or each second open groove 20a has a depth of between 50 μm and 100 μm. The conductive materials 3a1 are formed on the drive IC structure 1a by plating, and the conductive materials 3a1 can be solders.

Furthermore, the step of S102 is: electrically disposing the drive IC structure 1a and the LED array structure 2a on a substrate 4a. The substrate 4a can be a PCB (Printed Circuit Board). The substrate 4a has at least two input/output pads 40a. In addition, at least two conductive elements 5a are respectively connected between the drive IC structure 1a and one of the input/output pads 40a and between the LED array structure 2a and the other input/output pad 40a.

Moreover, the drive IC structure 1a has a plurality of drive IC pads 11a formed on a top surface thereof and a plurality of first conductive traces 12a. The drive IC pads 11a of the drive IC structure 1a correspond to the first open grooves 10a and each first conductive trace 12a is formed between each corresponding drive IC pad 11a and each corresponding first open groove 10a. In addition, the conductive materials 3a1 are respectively formed on the drive IC pads 11a of the drive IC structure 1a.

Furthermore, the LED array structure 2a has a plurality of LED pads 21a formed on a top surface thereof and a plurality of second conductive traces 22a. The LED pads 21a of the LED array structure 2a correspond to the second open grooves 20a and each second conductive trace 22a is formed between each corresponding LED pad 21a and each corresponding second open groove 20a. In addition, the LED array structure 2a has a plurality of LED dies 24a connected to the LED pads 21a via a plurality of third conductive traces 23a, respectively.

With regard to the first embodiment of the present invention, the drive IC pads 11a are arranged in a sawtooth shape in order to increase the density of the drive IC pads 11a, and the LED pads 21a are arranged in a line shape. However, the arrangement of the drive IC pads 11a and the LED pads 21a does not used to limit the present invention. Any type of arrangement of the pads is protected in the present invention. For example, the drive IC pads 11a are arranged in a line shape, and the LED pads 21a are arranged in a sawtooth shape; alternatively, the drive pads 11a and the LED pads 21a are arranged in a line shape or in a sawtooth shape.

Moreover, referring to FIGS. 1, 1B and 1C, the step of S104 is: slanting the substrate 4a by a predetermined angle θ during a reflow process in order to make the conductive materials 3a1 (as shown in FIG. 1B) change into liquid conductive materials 3a2 (as shown in FIG. 1C) and make the liquid conductive materials 3a2 traverse the first open grooves 10a and the second open grooves 20a in sequence to flow to the LED array structure 2a. In other words, each liquid conductive material 3a2 flows along the corresponding first conductive trace 12a, traverses the corresponding first open groove 10a and the corresponding second open groove 20a, flows along the lateral wall 20aW (each liquid conductive material 3a2 flows upward and downward along the lateral wall 20aW) of the corresponding second open groove 20a and the corresponding second conductive trace 22a in sequence, and then reaches the corresponding LED pads 21a.

Furthermore, referring to FIGS. 1, 1D1 and 1D2 (FIG. 1D2 shows a partial top view of FIG. 1D1), the step of S106 is: cooling the liquid conductive materials 3a2 to form a plurality of conductive structures 3A electrically connected between the drive IC structure 1a and the LED array structure 2a. In addition, each conductive structure 3A is divided into three portions that are a first portion 3A1, a second portion 3A2 and a third portion 3A3, and the second portion 3A2 is electrically connected between the first portion 3A1 and the third portion 3A3. The first portion 3A1 is formed on the corresponding drive IC pad 11a and the corresponding first conductive trace 12a. The second portion 3A2 traverses the corresponding first open groove 10a and the corresponding second open groove 20a in sequence and is formed on a lateral wall 20aW of the corresponding second open groove 20a. The third portion 3A3 are formed on the corresponding second conductive trace 22a in order to electrically connect with the corresponding LED pad 21a. Hence, each conductive structure 3A is electrically connected between the corresponding drive IC pad 11a of the drive IC structure 1a and the corresponding LED pad 21a of the LED array structure 2a.

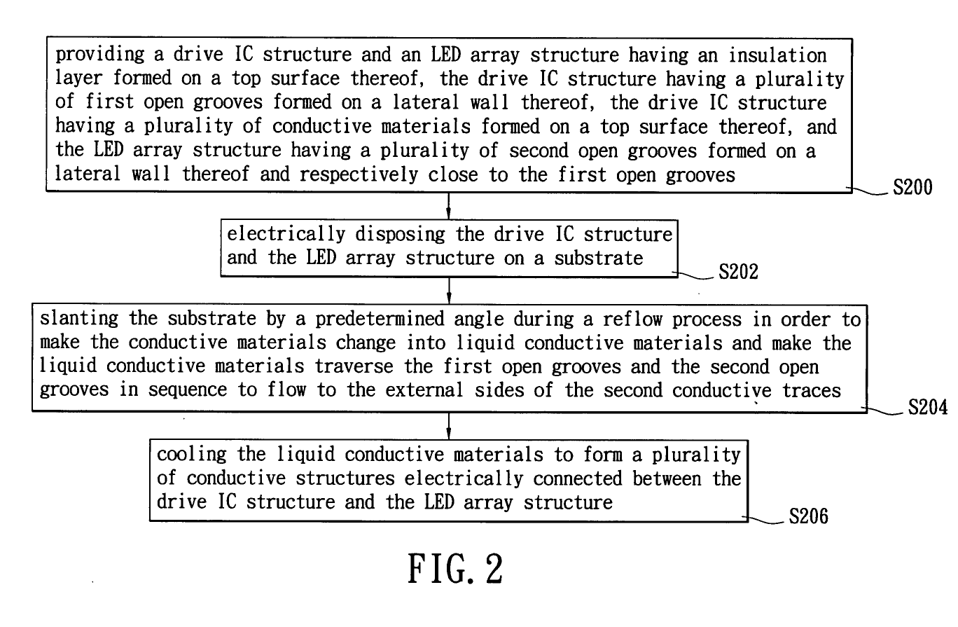

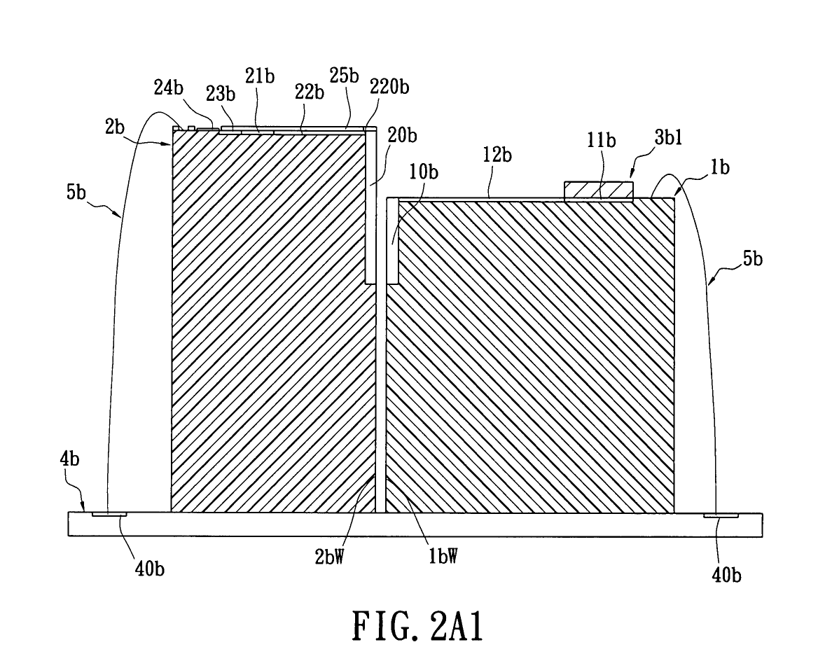

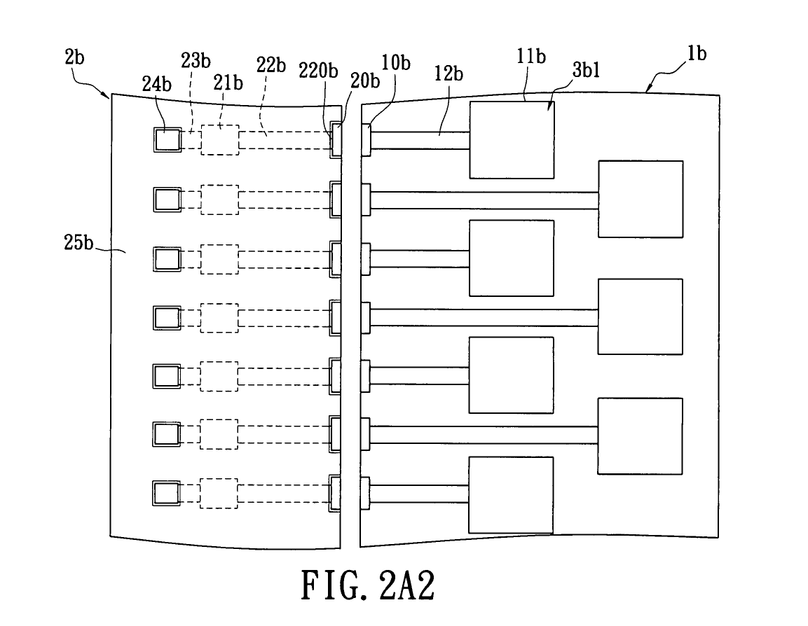

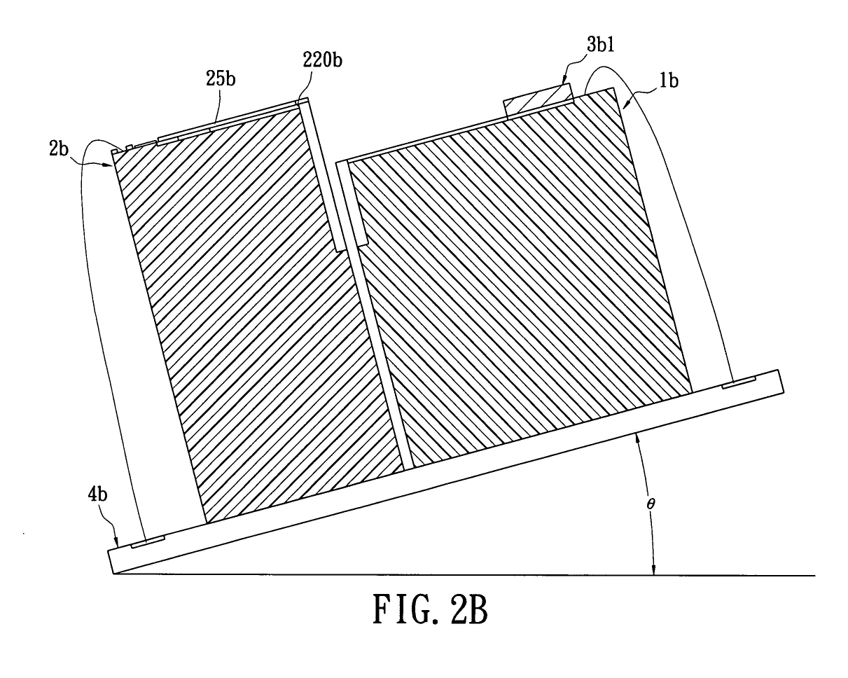

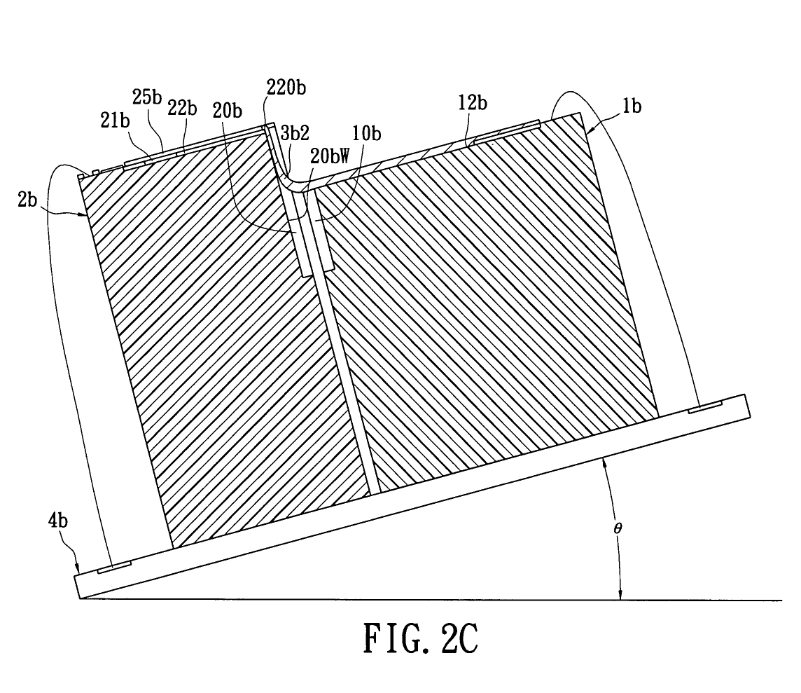

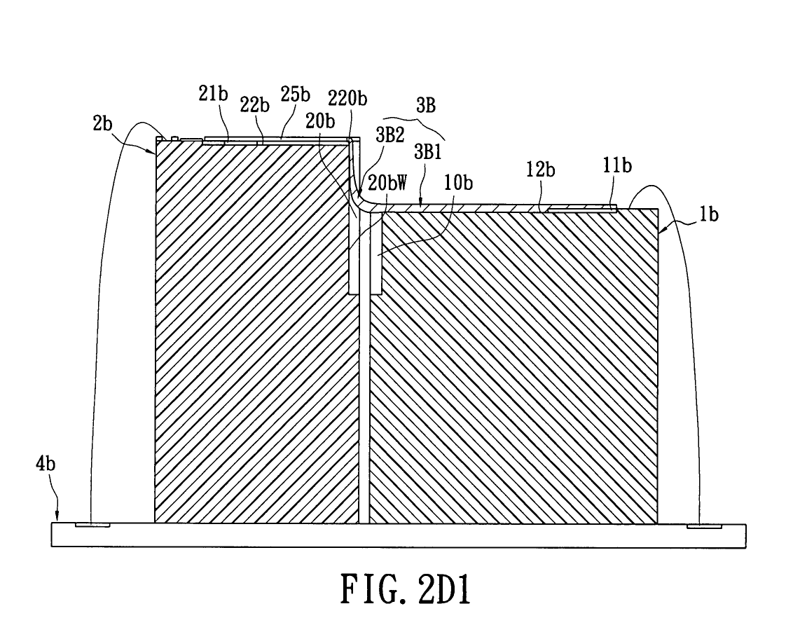

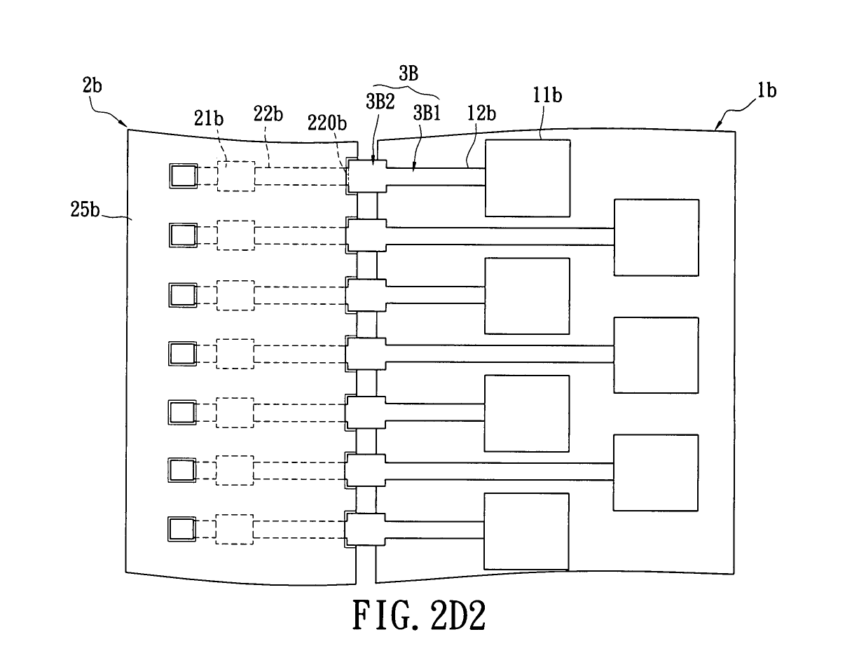

Referring to FIGS. 2 and 2A1 to 2D2, FIG. 2 shows a flowchart of a method for packaging a package structure module with high density electrical connections according to the second embodiment of the present invention, and FIGS. 2A1 to 2D2 show cross-sectional views of a package structure module with high density electrical connections according to the second embodiment of the present invention, at different stages of the packaging processes, respectively.

The second embodiment of the present invention provides a method for packaging a package structure module with high density electrical connections. The method includes following steps: referring to FIGS. 2, 2A1 and 2A2 (FIG. 2A2 shows a partial top view of FIG. 2A1), the step of S200 is: providing a drive IC structure 1b (a first structure) and an LED array structure 2b (a second structure) having an insulation layer 25b formed on a top surface thereof, the drive IC structure 1b having a plurality of first open grooves 10b formed on a lateral wall 1bW thereof, the drive IC structure 1b having a plurality of conductive materials 3b1 formed on a top surface thereof, and the LED array structure 2b having a plurality of second open grooves 20b formed on a lateral wall 2bW thereof and respectively close to the first open grooves 10b.

Moreover, the LED array structure 2b has a height higher than that of the drive IC structure 1b. Each first open groove 10b and each second open grooves 20b are respectively formed on the lateral wall 1bW of the drive IC structure 1b and the lateral wall 2bW of the LED array structure 2b via etching. In addition, each first open groove 10b or each second open groove 20b has a depth of between 50 μm and 100 μm. The conductive materials 3b1 are formed on the drive IC structure 1b by plating, and the conductive materials 3b1 can be solders.

Furthermore, the step of S202 is: electrically disposing the drive IC structure 1b and the LED array structure 2b on a substrate 4b. The substrate 4b can be a PCB (Printed Circuit Board). The substrate 4b has at least two input/output pads 40b. In addition, at least two conductive elements 5b are respectively connected between the drive IC structure 1b and one of the input/output pads 40b and between the LED array structure 2b and the other input/output pad 40b.

Moreover, the drive IC structure 1b has a plurality of drive IC pads 11b formed on a top surface thereof and a plurality of first conductive traces 12b. The drive IC pads 11b of the drive IC structure 1b correspond to the first open grooves 10b and each first conductive trace 12b is formed between each corresponding drive IC pad 11b and each corresponding first open groove 10b. In addition, the conductive materials 3b1 are respectively formed on the drive IC pads 11b of the drive IC structure 1b.

Furthermore, the LED array structure 2b has a plurality of LED pads 21b formed on a top surface thereof and a plurality of second conductive traces 22b. The LED pads 21b of the LED array structure 2b correspond to the second open grooves 20b and each second conductive trace 22b is formed between each corresponding LED pad 21b and each corresponding second open groove 20b. In addition, the LED array structure 2b has a plurality of LED dies 24b connected to the LED pads 21b via a plurality of third conductive traces 23b, respectively.

In addition, the insulation layer 25b formed on the top surface of the LED array structure 2b exposes the LED dies 24b and external sides 220b of the second conductive traces 22b.

With regard to the second embodiment of the present invention, the drive IC pads 11b are arranged in a sawtooth shape in order to increase the density of the drive IC pads 11b, and the LED pads 21b are arranged in a line shape.

Moreover, referring to FIGS. 2, 2B and 2C, the step of S204 is: slanting the substrate 4b by a predetermined angle θ during a reflow process in order to make the conductive materials 3b1 (as shown in FIG. 2B) change into liquid conductive materials 3b2 (as shown in FIG. 2C) and make the liquid conductive materials 3b2 traverse the first open grooves 10b and the second open grooves 20b in sequence to flow to the external sides 220b of the second conductive traces 22b. In other words, each liquid conductive material 3b2 flows along the corresponding first conductive trace 12b, traverses the corresponding first open groove 10b and the corresponding second open groove 20b, flows along the lateral wall 20bW (each liquid conductive material 3b2 flows upward and downward along the lateral wall 20bW) of the corresponding second open groove 20b, and then reaches the external side 220b of the corresponding second conductive trace 22b (the liquid conductive materials 3b2 is stopped on the external sides 220b of the second conductive traces 22b via the insulation layer 25b).

Furthermore, referring to FIGS. 2, 2D1 and 2D2 (FIG. 2D2 shows a partial top view of FIG. 2D1), the step of S206 is: cooling the liquid conductive materials 3b2 to form a plurality of conductive structures 3B electrically connected between the drive IC structure 1b and the LED array structure 2b. In addition, each conductive structure 3B is divided into a first portion 3B1 and a second portion 3B2 electrically connected to each other. The first portion 3B1 is formed on the corresponding drive IC pad 11b and the corresponding first conductive trace 12b. The second portion 3B2 traverses the corresponding first open groove 10b and the corresponding second open groove 20b in sequence and is formed on a lateral wall 20bW of the corresponding second open groove 20b and the external side 220b of the corresponding second conductive trace 22b due to the obstruction of the insulation layer 25b. Hence, each conductive structure 3B is electrically connected between the corresponding drive IC pad 11b of the drive IC structure 1b and the external side 220b of the corresponding second conductive trace 22b in order to make each corresponding drive IC pad 11b electrically connect with the corresponding LED pad 21b.

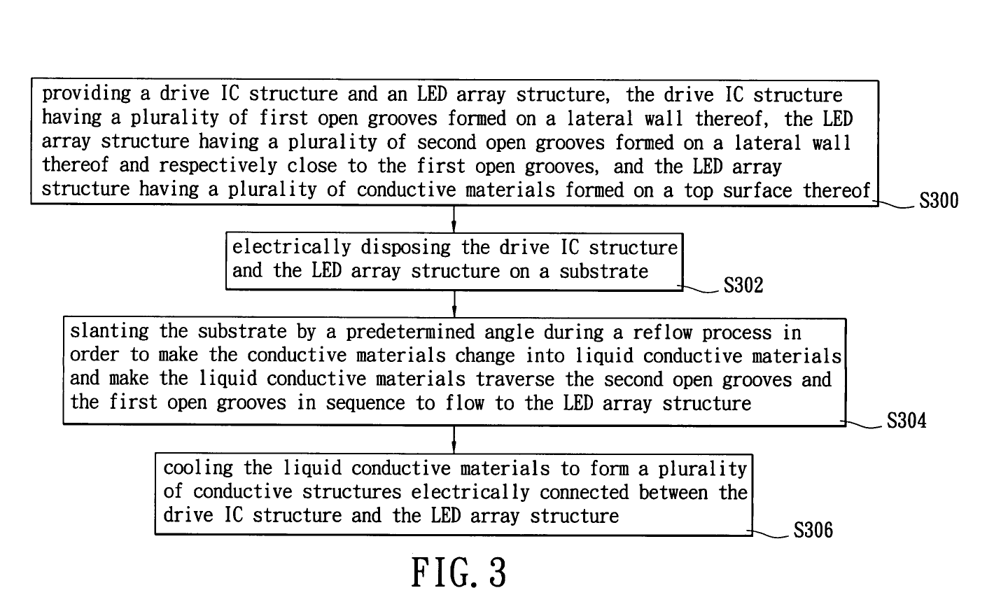

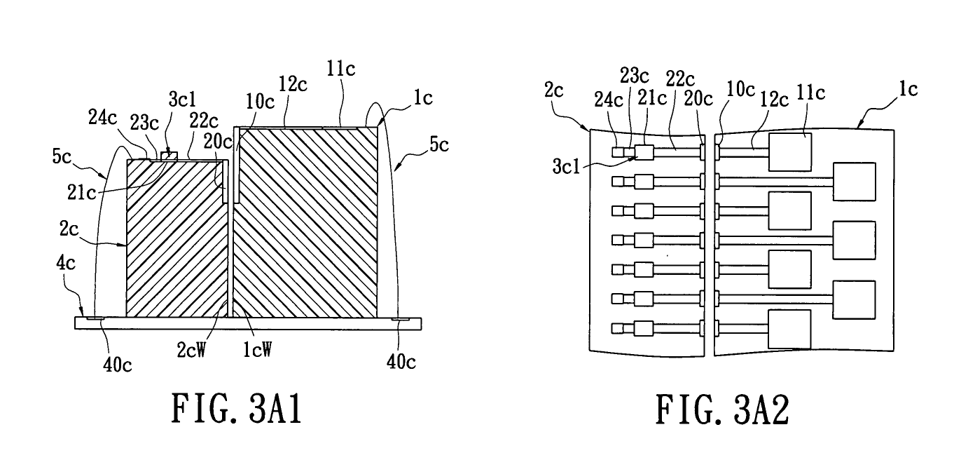

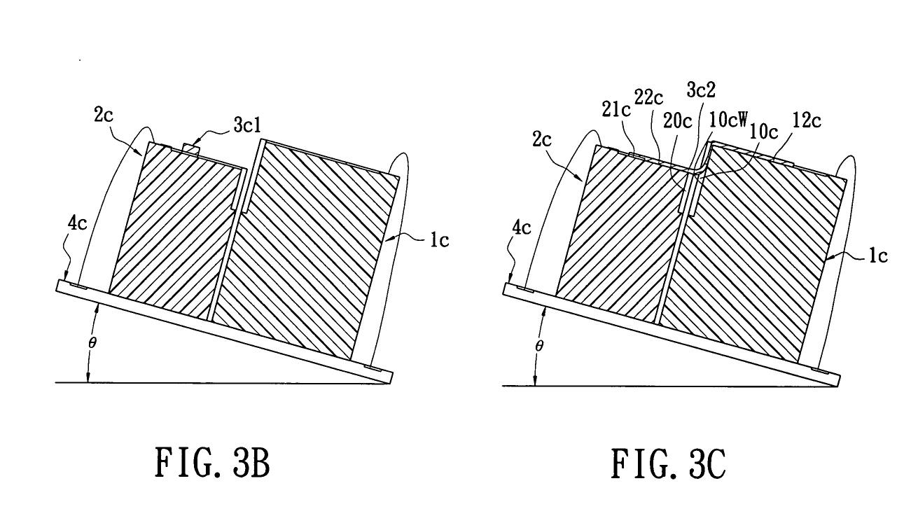

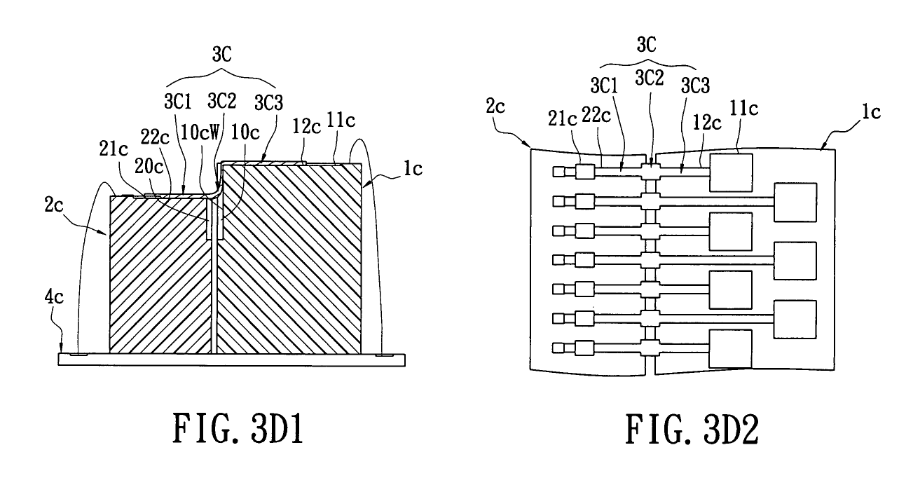

Referring to FIGS. 3 and 3A1 to 3D2, FIG. 3 shows a flowchart of a method for packaging a package structure module with high density electrical connections according to the third embodiment of the present invention, and FIGS. 3A1 to 3D2 show cross-sectional views of a package structure module with high density electrical connections according to the third embodiment of the present invention, at different stages of the packaging processes, respectively.

The third embodiment of the present invention provides a method for packaging a package structure module with high density electrical connections. The method includes following steps: referring to FIGS. 3, 3A1 and 3A2 (FIG. 3A2 shows a partial top view of FIG. 3A1), the step of S300 is: providing a drive IC structure 1c (a second structure) and an LED array structure 2c (a first structure), the drive IC structure 1c having a plurality of first open grooves 10c formed on a lateral wall 1cW thereof, the LED array structure 2c having a plurality of second open grooves 20c formed on a lateral wall 2cW thereof and respectively close to the first open grooves 10c, and the LED array structure 2c having a plurality of conductive materials 3c1 formed on a top surface thereof.

Moreover, the drive IC structure 1c has a height higher than that of the LED array structure 2c. Each first open groove 10c and each second open grooves 20c are respectively formed on the lateral wall 1cW of the drive IC structure 1c and the lateral wall 2cW of the LED array structure 2c via etching. In addition, each first open groove 10c or each second open groove 20c has a depth of between 50 μm and 100 μm. The conductive materials 3c1 are formed on the drive IC structure 1c by plating, and the conductive materials 3c1 can be solders.

Furthermore, the step of S302 is: electrically disposing the drive IC structure 1c and the LED array structure 2c on a substrate 4c. The substrate 4c can be a PCB (Printed Circuit Board). The substrate 4c has at least two input/output pads 40c. In addition, at least two conductive elements 5c are respectively connected between the drive IC structure 1c and one of the input/output pads 40c and between the LED array structure 2c and the other input/output pad 40c.

Moreover, the drive IC structure 1c has a plurality of drive IC pads 11c formed on a top surface thereof and a plurality of first conductive traces 12c. The drive IC pads 11c of the drive IC structure 1c correspond to the first open grooves 10c and each first conductive trace 12c is formed between each corresponding drive IC pad 11c and each corresponding first open groove 10c. Furthermore, the LED array structure 2c has a plurality of LED pads 21c formed on a top surface thereof and a plurality of second conductive traces 22c. The LED pads 21c of the LED array structure 2c correspond to the second open grooves 20c and each second conductive trace 22c is formed between each corresponding LED pad 21c and each corresponding second open groove 20c. In addition, the conductive materials 3c1 are respectively formed on the LED pads 21C of the LED array structure 1c. The LED array structure 2c has a plurality of LED dies 24c connected to the LED pads 21c via a plurality of third conductive traces 23c, respectively.

With regard to the first embodiment of the present invention, the drive IC pads 11c are arranged in a sawtooth shape in order to increase the density of the drive IC pads 11c, and the LED pads 21c are arranged in a line shape.

Moreover, referring to FIGS. 3, 3B and 3C, the step of S304 is: slanting the substrate 4c by a predetermined angle θ during a reflow process in order to make the conductive materials 3c1 (as shown in FIG. 3B) change into liquid conductive materials 3c2 (as shown in FIG. 3C) and make the liquid conductive materials 3c2 traverse the second open grooves 20c and the first open grooves 10c in sequence to flow to the LED array structure 2c. In other words, each liquid conductive material 3c2 flows along the corresponding second conductive trace 22c, traverses the corresponding second open groove 20c and the corresponding first open groove 10c, flows along the lateral wall 10cW (each liquid conductive material 3c2 flows upward and downward along the lateral wall 10cW) of the corresponding first open groove 10c and the corresponding first conductive trace 12c in sequence, and then reaches the corresponding drive IC pads 11c.

Furthermore, referring to FIGS. 3, 3D1 and 3D2 (FIG. 3D2 shows a partial top view of FIG. 3D1), the step of S306 is: cooling the liquid conductive materials 3c2 to form a plurality of conductive structures 3C electrically connected between the drive IC structure 1c and the LED array structure 2c. In addition, each conductive structure 3C is divided into three portions that are a first portion 3C1, a second portion 3C2 and a third portion 3C3, and the second portion 3C2 is electrically connected between the first portion 3C1 and the third portion 3C3. The first portion 3C1 is formed on the corresponding LED pad 21c and the corresponding second conductive trace 22c. The second portion 3C2 traverses the corresponding second open groove 20c and the corresponding first open groove 10c in sequence and is formed on a lateral wall 10cW of the corresponding first open groove 10a. The third portion 3C3 is formed on the corresponding first conductive trace 12c in order to electrically connect with the corresponding drive IC pad 11c. Hence, each conductive structure 3C is electrically connected between the corresponding drive IC pad 11c of the drive IC structure 1c and the corresponding LED pad 21c of the LED array structure 2c.

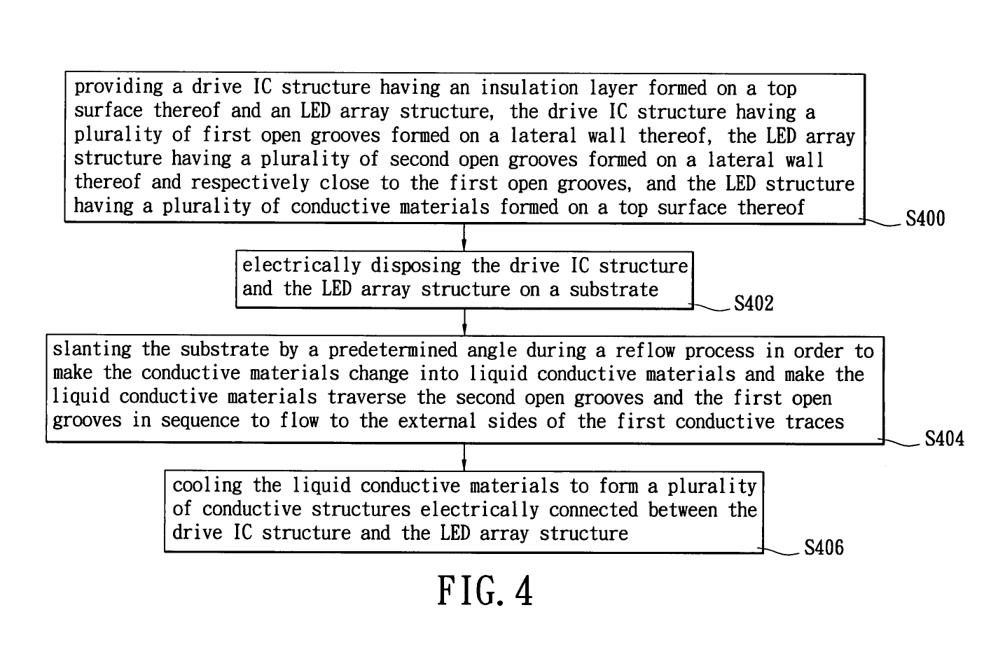

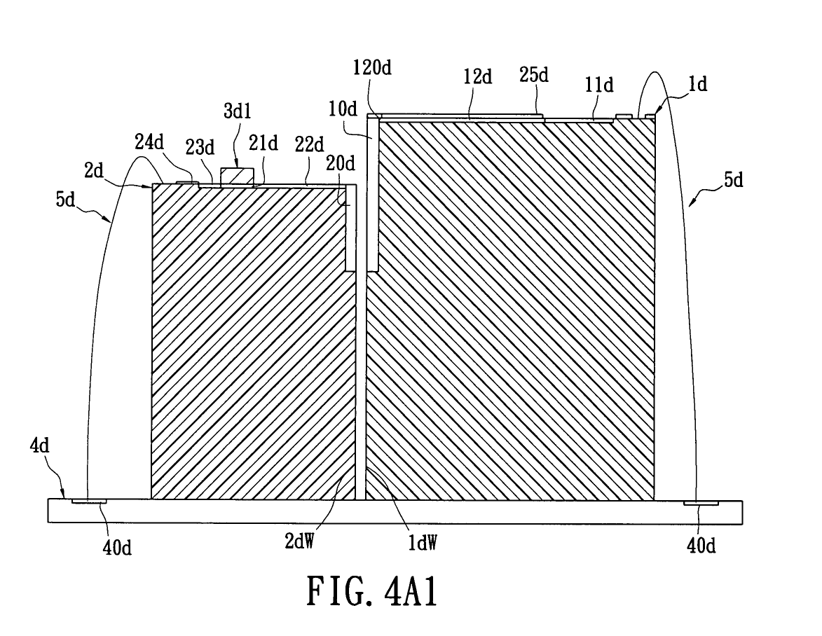

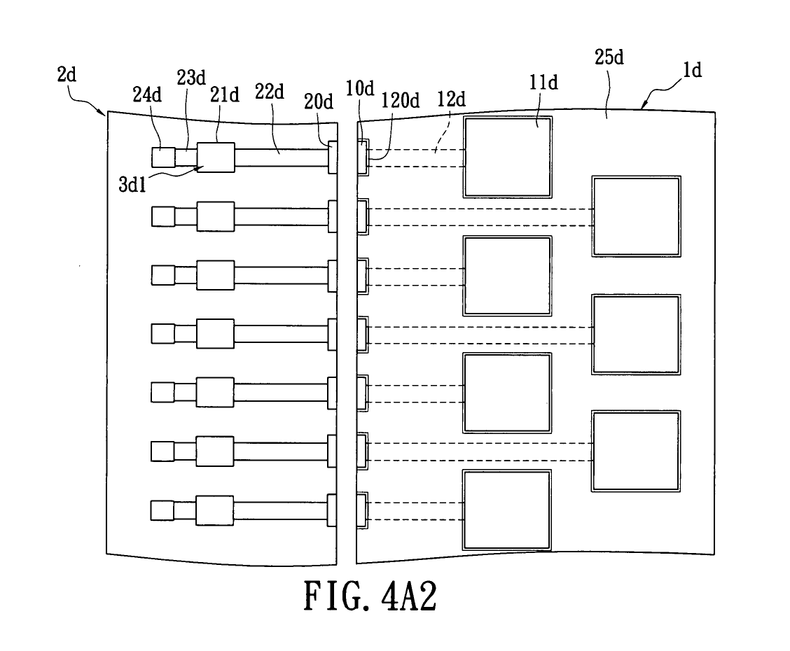

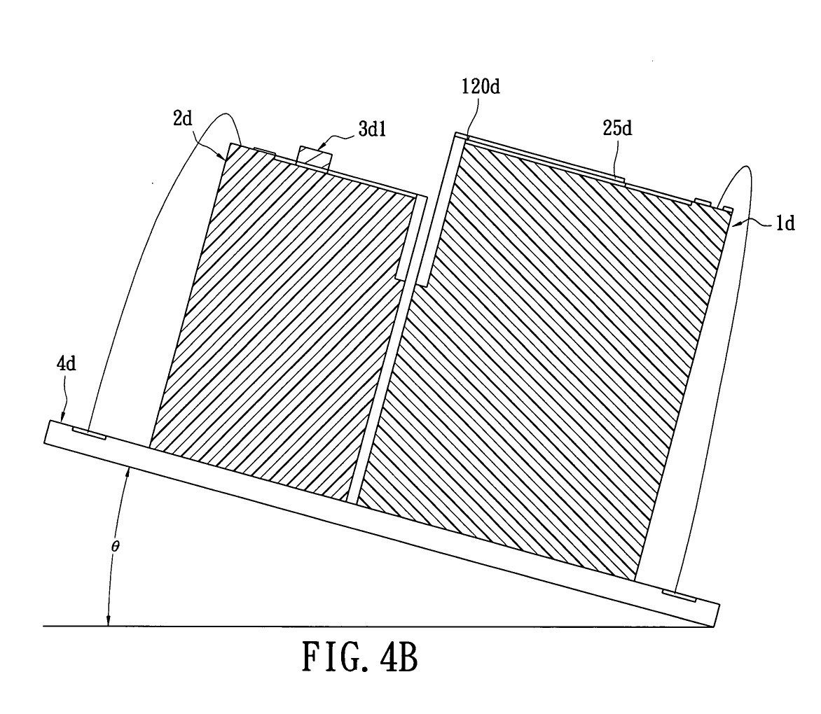

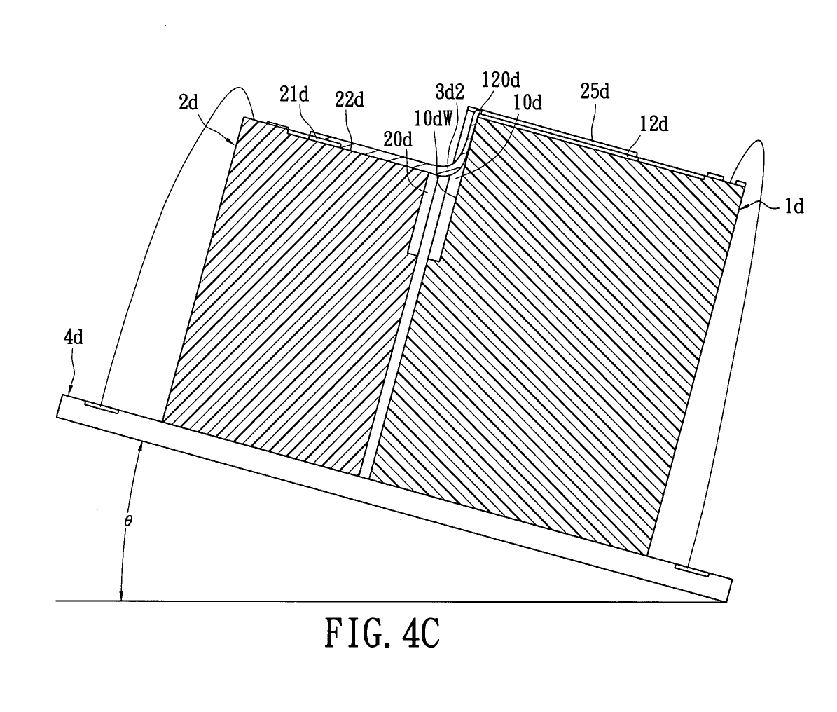

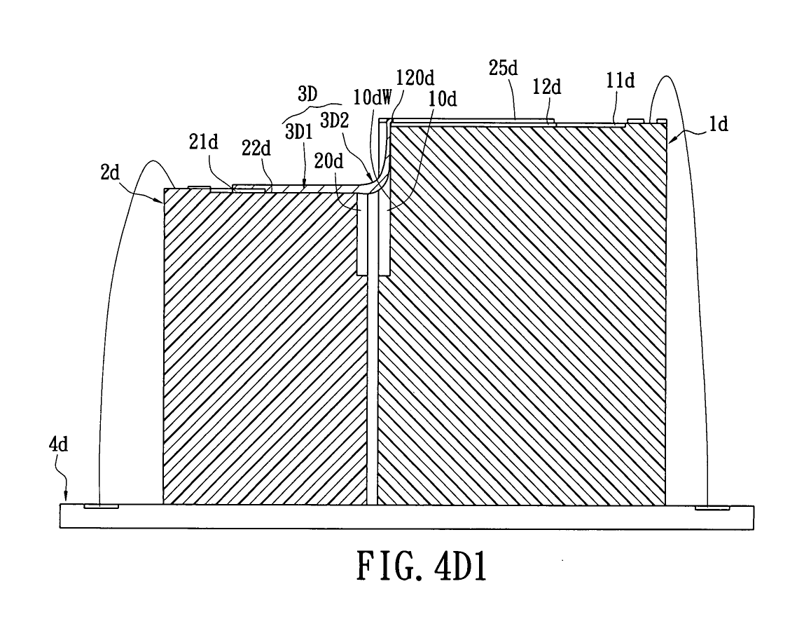

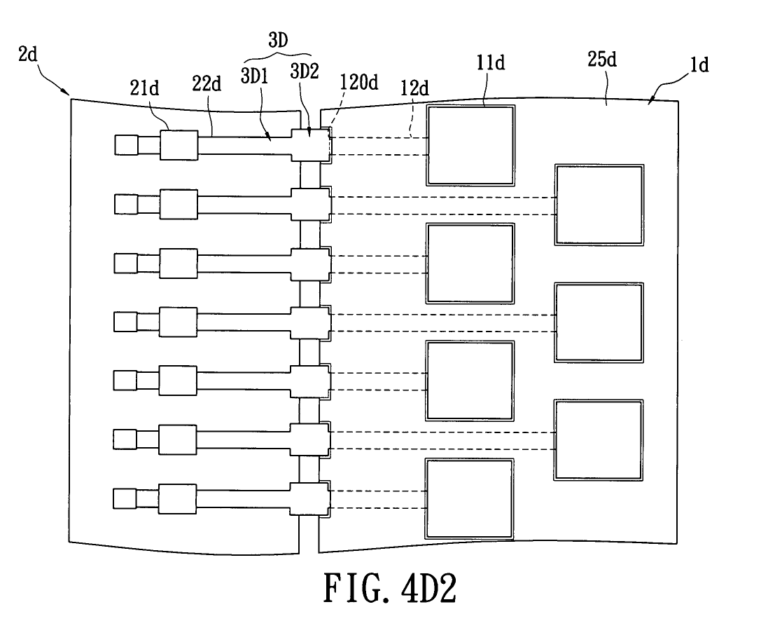

Referring to FIGS. 4 and 4A 1 to 4D2, FIG. 4 shows a flowchart of a method for packaging a package structure module with high density electrical connections according to the third embodiment of the present invention, and FIGS. 4A1 to 4D2 show cross-sectional views of a package structure module with high density electrical connections according to the fourth embodiment of the present invention, at different stages of the packaging processes, respectively.

The fourth embodiment of the present invention provides a method for packaging a package structure module with high density electrical connections. The method includes following steps: referring to FIGS. 4, 4A1 and 4A2 (FIG. 4A2 shows a partial top view of FIG. 4A1), the step of S400 is: providing a drive IC structure 1d (a second structure) having an insulation layer 25d formed on a top surface thereof and an LED array structure 2d (a first structure), the drive IC structure 1d having a plurality of first open grooves 10d formed on a lateral wall 1dW thereof, the LED array structure 2d having a plurality of second open grooves 20d formed on a lateral wall 2dW thereof and respectively close to the first open grooves 10d, and the LED structure 2d having a plurality of conductive materials 3d1 formed on a top surface thereof.

Moreover, the drive IC structure 1d has a height higher than that of the LED array structure 2d. Each first open groove 10d and each second open grooves 20d are respectively formed on the lateral wall 1dW of the drive IC structure 1d and the lateral wall 2dW of the LED array structure 2d via etching. In addition, each first open groove 10d or each second open groove 20d has a depth of between 50 μm and 100 μm. The conductive materials 3d1 are formed on the drive IC structure 1d by plating, and the conductive materials 3d1 can be solders.

Furthermore, the step of S402 is: electrically disposing the drive IC structure 1d and the LED array structure 2d on a substrate 4d. The substrate 4d can be a PCB (Printed Circuit Board). The substrate 4d has at least two input/output pads 40d. In addition, at least two conductive elements 5d are respectively connected between the drive IC structure 1d and one of the input/output pads 40d and between the LED array structure 2d and the other input/output pad 40d.

Moreover, the drive IC structure 1d has a plurality of drive IC pads 11d formed on a top surface thereof and a plurality of first conductive traces 12d. The drive IC pads 11d of the drive IC structure 1d correspond to the first open grooves 10d and each first conductive trace 12d is formed between each corresponding drive IC pad 1d and each corresponding first open groove 10d. Furthermore, the LED array structure 2d has a plurality of LED pads 21d formed on a top surface thereof and a plurality of second conductive traces 22d. The LED pads 21d of the LED array structure 2d correspond to the second open grooves 20d and each second conductive trace 22d is formed between each corresponding LED pad 21d and each corresponding second open groove 20d. In addition, the conductive materials 3d1 are respectively formed on the LED pads 21d of the LED array structure 2d. The LED array structure 2d has a plurality of LED dies 24d connected to the LED pads 21d via a plurality of third conductive traces 23d, respectively.

In addition, the insulation layer 25d formed on the top surface of the drive IC structure 1d is used to expose the drive IC pads 11d and external sides 120d of the first conductive traces 12d.

With regard to the fourth embodiment of the present invention, the drive IC pads 11d are arranged in a sawtooth shape in order to increase the density of the drive IC pads 11d, and the LED pads 21d are arranged in a line shape.

Moreover, referring to FIGS. 4, 4B and 4C, the step of S404 is: slanting the substrate 4d by a predetermined angle θ during a reflow process in order to make the conductive materials 3d1 (as shown in FIG. 4B) change into liquid conductive materials 3d2 (as shown in FIG. 4C) and make the liquid conductive materials 3d2 traverse the second open grooves 20d and the first open grooves 10d in sequence to flow to the external sides 120d of the first conductive traces 12d. In other words, each liquid conductive material 3d2 flows along the corresponding second conductive trace 22d, traverses the corresponding second open groove 20d and the corresponding first open groove 10d, flows along the lateral wall 10dW (each liquid conductive material 3d2 flows upward and downward along the lateral wall 10dW) of the corresponding first open groove 10d, and then reaches the external side 120d of the corresponding first conductive trace 12d (the liquid conductive materials 3d2 is stopped on the external sides 120d of the first conductive traces 12d via the insulation layer 25d).

Furthermore, referring to FIGS. 4, 4D1 and 4D2 (FIG. 4D2 shows a partial top view of FIG. 4D1), the step of S406 is: cooling the liquid conductive materials 3d2 to form a plurality of conductive structures 3D electrically connected between the drive IC structure 1d and the LED array structure 2d. In addition, each conductive structure 3D is divided into a first portion 3D1 and a second portion 3D2 electrically connected to each other. The first portion 3D1 is formed on the corresponding LED pad 21d and the corresponding second conductive trace 22d. The second portion 3D2 traverses the corresponding second open groove 20d and the corresponding first open groove 10d in sequence and is formed on a lateral wall 10dW of the corresponding first open groove 10d and the external side 120d of the corresponding first conductive trace 12d due to the obstruction of the insulation layer 25d. Hence, each conductive structure 3D is electrically connected between the corresponding LED pad 21d of the LED array structure 1d and the external side 120d of the corresponding first conductive trace 12d in order to make each corresponding drive IC pad 11d electrically connect with the corresponding LED pad 21d.

In addition, according to designer's requirements, one structure that has the conductive materials thereon does not need to form open grooves. In other words, such as the first embodiment, the first open grooves 10a do not need to form on the drive IC structure 1a firstly. Hence, the liquid conductive materials 3a2 only needs to respectively traverse the second open grooves 20a of the LED array structure 2a, the conductive structures 3B are formed between the drive IC structure 1a and the LED array structure 2a. Such as the third embodiment,

the second open grooves 20c do not need to form on the LED array structure 2c firstly. Hence, the liquid conductive materials 3c2 only needs to respectively traverse the first open grooves 10c of the drive IC structure 1c, the conductive structures 3C are formed between the drive IC structure 1c and the LED array structure 2c.

In conclusion, the package structure module is an LED array structure module, and the LED array structure module is a light exposure module that can be applied to an EPG (Electrophotography) printer.

The features of the present invention include (1) manufacturing concave grooves and pads electrically connected to each other on an LED array structure and a drive IC structure; (2) electroplating solder materials onto the drive IC structure; (3) the drive IC structure and the LED array structure are approximated to each other and electrically disposed on a PCB, and there is a height difference between the drive IC structure and the LED array structure; (4) slanting the PCB by a predetermined angle during a reflow process in order to make the solder materials flow to the LED array structure on a low position to connect to the pads of the LED array structure. Hence, the present invention can reach a high density electrical connection with 600˜1200 dip. Therefore, the present invention can reduce product size, material cost, and manufacturing cost due to high density electrical connection.

Therefore, the present invention does not need to use a wire-bonding process as in the prior art that requires a long time. Hence, the present invention not only can reduce product size, material cost, and manufacturing cost, but also increases production speed.

Although the present invention has been described with reference to the preferred best molds thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A package structure module with high density electrical connections, comprising:
a first structure;
a second structure having a height higher than that of the first structure, wherein the second structure has a plurality of second open grooves formed on a lateral wall thereof and close to the first structure; and
a plurality of conductive structures respectively traverse the second open grooves in order to make the conductive structures electrically connect between the first structure and the second structure.

2. The package structure module as claimed in claim 1, wherein the first structure has a plurality of first open grooves formed on a lateral wall thereof and respectively facing the second open grooves, and the conductive structures respectively traverse the first open grooves.

3. The package structure module as claimed in claim 1, wherein each second open groove has a depth of between 50 μm and 100 μm.

4. The package structure module as claimed in claim 2, wherein each first open groove has a depth of between 50 μm and 100 μm.

5. The package structure module as claimed in claim 1, wherein the first structure is a drive IC structure, and the second structure is an LED array structure.

6. The package structure module as claimed in claim 1, wherein the first structure is an LED array structure, and the second structure is a drive IC structure.

7. The package structure module as claimed in claim 1, further comprising a substrate having at least two input/output pads, wherein the first structure and the second structure are electrically disposed on the substrate.

8. The package structure module as claimed in claim 7, further comprising at least two conductive elements respectively connected between the first structure and one of the input/output pads and between the second structure and the other input/output pad.

9. The package structure module as claimed in claim 2, wherein the first structure has a plurality of pads formed on a top surface thereof and a plurality of first conductive traces, and the pads of the first structure correspond to the first open grooves and each first conductive trace is formed between each corresponding pad of the first structure and each corresponding first open groove; wherein the second structure has a plurality of pads formed on a top surface thereof and a plurality of second conductive traces, and the pads of the second structure correspond to the second open grooves and each second conductive trace is formed between each corresponding pad of the second structure and each corresponding second open groove.

10. The package structure module as claimed in claim 9, wherein each conductive structure is divided into three portions that are a first portion, a second portion and a third portion, and the second portion is electrically connected between the first portion and the third portion; wherein the first portion is formed on the corresponding pad of the first structure and the corresponding first conductive trace, the second portion traverses the corresponding first open groove and the corresponding second open groove in sequence and is formed on a lateral wall of the corresponding second open groove, and the third portion is formed on the corresponding second conductive trace in order to electrically connect with the corresponding pad of the second structure.

11. The package structure module as claimed in claim 9, wherein the second structure has an insulation layer formed on a top surface thereof in order to expose the pads and external sides of the second conductive traces.

12. The package structure module as claimed in claim 11, wherein each conductive structure is divided into a first portion and a second portion electrically connected to each other, the first portion is formed on the corresponding pad of the first structure and the corresponding first conductive trace, and the second portion traverses the corresponding first open groove and the corresponding second open groove in sequence and is formed on a lateral wall of the corresponding second open groove and the external side of the corresponding second conductive trace due to the obstruction of the insulation layer.

13. A method for packaging a package structure module with high density electrical connections, comprising:
providing a first structure and a second structure having a height higher than that of the first structure, wherein the first structure has a plurality of conductive materials formed on a top surface thereof, and the second structure has a plurality of second open grooves formed on a lateral wall thereof and close to the first structure;
electrically disposing the first structure and the second structure on a substrate;
slanting the substrate by a predetermined angle during a reflow process in order to make the conductive materials change into liquid conductive materials and make the liquid conductive materials traverse the second open grooves to flow to the second structure; and
cooling the liquid conductive materials to form a plurality of conductive structures electrically connected between the first structure and the second structure.

14. The method as claimed in claim 13, wherein the first structure has a plurality of first open grooves formed on a lateral wall thereof and respectively facing the second open grooves, and the liquid conductive materials respectively traverse the first open grooves.

15. The method as claimed in claim 13, wherein each second open groove has a depth of between 50 μm and 100 μm.

16. The method as claimed in claim 14, wherein each first open groove has a depth of between 50 μm and 100 μm.

17. The method as claimed in claim 14, wherein the first and the second open grooves are formed via etching.

18. The method as claimed in claim 13, wherein the first structure is a drive IC structure, and the second structure is an LED array structure.

19. The method as claimed in claim 13, wherein the substrate has at least two input/output pads, and at least two conductive elements are respectively connected between the first structure and one of the input/output pads and between the second structure and the other input/output pad.

20. The method as claimed in claim 14, wherein the first structure has a plurality of pads formed on a top surface thereof and a plurality of first conductive traces, and the pads of the first structure correspond to the first open grooves and each first conductive trace is formed between each corresponding pad of the first structure and each corresponding first open groove; wherein the second structure has a plurality of pads formed on a top surface thereof and a plurality of second conductive traces, and the pads of the second structure correspond to the second open grooves and each second conductive trace is formed between each corresponding pad of the second structure and each corresponding second open groove.

21. The method as claimed in claim 20, wherein each conductive structure is electrically connected between the corresponding pad of the first structure and the corresponding pad of the second structure.

22. The method as claimed in claim 20, wherein each conductive structure is divided into three portions that are a first portion, a second portion and a third portion, and the second portion is electrically connected between the first portion and the third portion; wherein the first portion is formed on the corresponding pad of the first structure and the corresponding first conductive trace, the second portion traverses the corresponding first open groove and the corresponding second open groove in sequence and is formed on a lateral wall of the corresponding second open groove, and the third portion is formed on the corresponding second conductive trace in order to electrically connect with the corresponding pad of the second structure.

23. The method as claimed in claim 20, wherein the second structure has an insulation layer formed on a top surface thereof in order to expose the pads and external sides of the second conductive traces.

24. The method as claimed in claim 23, wherein each conductive structure is divided into a first portion and a second portion electrically connected to each other, the first portion is formed on the corresponding pad of the first structure and the corresponding first conductive trace, and the second portion traverses the corresponding first open groove and the corresponding second open groove in sequence and is formed on a lateral wall of the corresponding second open groove and the external side of the corresponding second conductive trace due to the obstruction of the insulation layer.
